(19) United States
(12) Patent Application Publication
(10) Pub. No.: US 2025/0063800 A1
(43) Pub. Date: Feb. 20, 2025

(54) Wide Bandgap Trench Gate Semiconductor Device with Buried Gate

(71) Applicant: Wolfspeed, Inc., Durham, NC (US)

(72) Inventor: Thomas Edgar Harrington, III, Durham, NC (US)

(21) Appl. No.: 18/449,458

(22) Filed: Aug. 14, 2023

(51) Int. Cl. H01L 29/423; H01L 29/06; H01L 29/16; H01L 29/49; H01L 29/66; H01L 29/739; H01L 29/78

(52) U.S. Cl. CPC H01L 29/4236; H01L 29/0607; H01L 29/1608; H01L 29/42368; H01L 29/42376; H01L 29/4933; H01L 29/66348; H01L 29/66553; H01L 29/66734; H01L 29/7397; H01L 29/7813

(57) ABSTRACT

Wide bandgap trench gate semiconductor devices are provided. In one example, a semiconductor device includes a wide bandgap semiconductor structure. The wide bandgap semiconductor structure includes a drift region of a first conductivity type and a well region of a second conductivity type. The semiconductor device includes a gate trench in the wide bandgap semiconductor structure. The gate trench extends through the well region into the drift region. The semiconductor device includes a buried gate structure in the gate trench. The buried gate structure includes a gate polysilicon layer and a gate silicide layer.

### FIELD

The present disclosure relates generally to semiconductor devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), bipolar junction transistors (“BJTs”), Insulated Gate Bipolar Transistors (“IGBT”), Junction Barrier Schottky diodes, Gate Turn-Off Transistors (“GTO”), MOS-controlled thyristors and various other devices. These power semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor device. The semiconductor device includes a wide bandgap semiconductor structure. The wide bandgap semiconductor structure includes a drift region of a first conductivity type and a well region of a second conductivity type. The semiconductor device includes a gate trench in the wide bandgap semiconductor structure. The gate trench extends through the well region into the drift region. The semiconductor device includes a buried gate structure in the gate trench. The buried gate structure includes a gate polysilicon layer and a gate silicide layer.

Another example embodiment of the present disclosure is directed to a semiconductor device. The semiconductor device includes a wide bandgap semiconductor structure. The wide bandgap semiconductor structure includes a drift region of a first conductivity type and a well region of a second conductivity type. The semiconductor device includes a gate trench in the wide bandgap semiconductor structure. The gate trench extends through the well region into the drift region. The semiconductor device includes a gate structure in the gate trench. The semiconductor device includes a dielectric layer in the gate trench on the gate structure. The semiconductor device includes a spacer layer in the gate trench and between the dielectric layer and a sidewall of the gate trench. The semiconductor device includes a gate dielectric layer in the gate trench between the gate structure and the drift region.

Another example embodiment of the present disclosure is directed to a method of fabricating a semiconductor device. The method includes forming a gate trench in a wide bandgap semiconductor structure. The method includes forming a buried gate structure in the gate trench. The buried gate structure includes a gate polysilicon layer and a gate silicide layer. The method includes forming a dielectric layer in the gate trench on the buried gate structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of an example semiconductor device according to example embodiments of the present disclosure;

FIG. 2 depicts a cross-sectional view of an example semiconductor device according to example embodiments of the present disclosure;

FIG. 3 depicts a cross-sectional view of an example semiconductor device according to example embodiments of the present disclosure;

FIG. 4 depicts a cross-sectional view of an example semiconductor device according to example embodiments of the present disclosure;

FIG. 5 depicts a cross-sectional view of an example semiconductor device according to example embodiments of the present disclosure;

FIG. 6 depicts a flow chart diagram of an example method according to example embodiments of the present disclosure;

FIG. 7-FIG. 16 depict aspects of example fabrication of an example semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

A power semiconductor device may have a semiconductor substrate, such as a silicon carbide substrate having a first conductivity type (e.g., an n-type substrate), on which an epitaxial layer structure having the first conductivity type (e.g., n-type) is formed. A portion of this epitaxial layer structure (which may include one or more separate layers) functions as a drift region of the power semiconductor device. The device typically includes an “active region,” which includes one or more power semiconductor devices that have a junction such as a p-n junction. The active region may be formed on and/or in the drift region. The active region acts as a main junction for blocking voltage in the reverse bias direction and providing current flow in the forward bias direction. The power semiconductor devices may have a unit cell structure in which the active region of each power semiconductor device includes a plurality of individual “unit cell” devices that are electrically connected in parallel and that together function as a single power semiconductor device.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure. Herein, the term “semiconductor structure” refers to a structure that includes one or more semiconductor layers, such as semiconductor substrates and/or semiconductor epitaxial layers.

Vertical power semiconductor devices, including a MOSFET transistor or an IGBT transistor, can have a standard gate electrode design in which the gate electrode of the transistor is formed on top of the semiconductor structure. Alternatively, the power semiconductor devices may have the gate electrode in a gate trench within the semiconductor structure. Power semiconductor devices having trench gate electrodes are typically referred to as trench gate devices (e.g., trench gate MOSFETs or trench gate IGBTs). With the standard gate electrode design, the channel region of each unit cell transistor is horizontally disposed underneath the gate electrode. In contrast, in the trench gate design, the channel is vertically disposed. Trench gate devices may provide enhanced performance but may require a more complicated manufacturing process(s).

Silicon carbide-based trench gate vertical power devices may be attractive due to their inherent lower specific on-resistance, which may result in more efficient operation for power switching operations requiring low-to-moderate reverse blocking voltage levels (e.g., about 650-1200V). Trench gate vertical power devices may exhibit a lower specific resistance during on-state operation since the channel is formed on the sidewall of the gate trench, and the trench design reduces the overall pitch of the device, allowing for increased integration. Moreover, the carrier mobility in the sidewall channel of a trench gate power semiconductor device (e.g., trench gate MOSFET) has been found to be 2-4 times higher than the corresponding carrier mobility in the channel of a planar (e.g., lateral structure) device. This increased carrier mobility also enhances the current density.

It can be desirable to scale trench gate devices to smaller and smaller geometries to provide for increased cell density, increased power density, and/or lower on-resistance for the trench gate semiconductor device. However, complexities due to geometries of trench gate semiconductor devices can pose challenges in scaling. For instance, use of contact holes or metallized vias to connect a source contact to well tie-in regions adjacent the gate trench can increase a pitch (e.g., lateral distance) of unit cells. In addition, having trench gate electrodes exposed through a surface of the trench may require contact masking and contact etch geometries that may increase the pitch of unit cells.

Examples aspects of the present disclosure are directed to trench gate semiconductor devices (e.g., trench gate MOSFETs, trench gate IGBTs) having a buried gate contact within a gate trench of the semiconductor device. The gate trench may be in a wide bandgap semiconductor structure (e.g., silicon carbide semiconductor structure). In some examples, a gate structure for the semiconductor device may be a multilayer gate structure including a first gate layer (e.g., a gate polysilicon layer) and a second gate layer on the first gate layer (e.g., a gate silicide layer). According to examples of the present disclosure, the multilayer gate structure is completely buried within the gate trench so that no portion of the gate structure is disposed above or outside of the gate trench. For instance, the gate structure may be covered within the gate trench (e.g., by one or more dielectric layers).

In some examples, the semiconductor device has a metallization layer on the semiconductor structure. The metallization layer may be, for instance, a source metallization layer for the semiconductor device. The semiconductor device may have a dielectric layer (e.g., silicate glass layer) on the gate structure in the gate trench (e.g., covering the gate structure). The dielectric layer, in some examples, may have a surface that is coplanar with an upper surface of the semiconductor structure. The metallization layer may have a planar surface contacting the semiconductor structure and the dielectric layer. In some examples, the dielectric layer electrically insulates the gate structure buried in the gate trench from the metallization layer.

In some examples, the gate structure includes a gate silicide layer. The gate silicide layer may be a different material than a silicide layer on the well tie-in regions (e.g., to provide an ohmic contact) of the semiconductor device adjacent the gate structure. In some examples, the silicide layer of the gate structure is the same material as a silicide layer on the well tie-in regions of the semiconductor device.

In some examples, the gate silicide layer includes tantalum silicide Ta_{y}Siₓ or tungsten silicide W_{y}Siₓ, where x is in a range of about 2.0 to about 3.0. In these examples, the gate silicide layer may be stable at higher temperatures required to planarize the dielectric layer in the gate trench and/or to subsequently form the silicide layers on the well tie-in regions of the semiconductor structure. In some examples, the silicide layer on the well tie-in regions of the semiconductor device includes nickel silicide, tungsten silicide, titanium silicide, aluminum silicide, molybdenum silicide, aluminum-titanium silicide, nickel-titanium-aluminum silicide or titanium-tungsten silicide.

In some examples, the semiconductor devices may include a field shielding region below the gate trench. For instance, using opposite doping (p+ for an nMOSFET or nIGBT) in the semiconductor region below a gate dielectric layer at the bottom of the gate trench may provide electric field shielding of the gate dielectric layer at the bottom of the gate trench. The shield region may reduce the electric field seen by the gate dielectric layer and hence prevent dielectric breakdown and/or premature dielectric wear out.

Aspects of the present disclosure provide technical effects and benefits. For instance, aspects of the present disclosure may allow for better scaling of wide bandgap semiconductor device cells (e.g., trench gate MOSFET cells and trench gate IGBT cells) by burying and metallizing the gate electrode within the trench to reduce the need to have contact masking and contact etch geometries contributing to the pitch within each cell. In addition, active-area-consuming gate-bussing structures may be reduced due to the metallized gate structures (e.g., multilayer gate structures with gate silicide layer). With the gate structure buried, the surface region becomes planar such that source metallization makes contact to the source and well-tie regions without having to dive down into a contact or use a metallized plug in a contact hole to connect to the source and well-tie regions. Without the need for a contact photo/etch step to create a contact opening, the cell structure becomes completely self-aligned. The self-aligned nature of the cell with embedded gate metallization is a significant advantage to scaling the cell to smaller geometries, allowing for increased cell density and power density, and for lower specific on-resistance. In addition, reducing the cell pitch and implementing thick bottom dielectric with a bottom field shield underneath reduces the need for separate field-reducing p+ doping column(s).

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based transistor devices for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

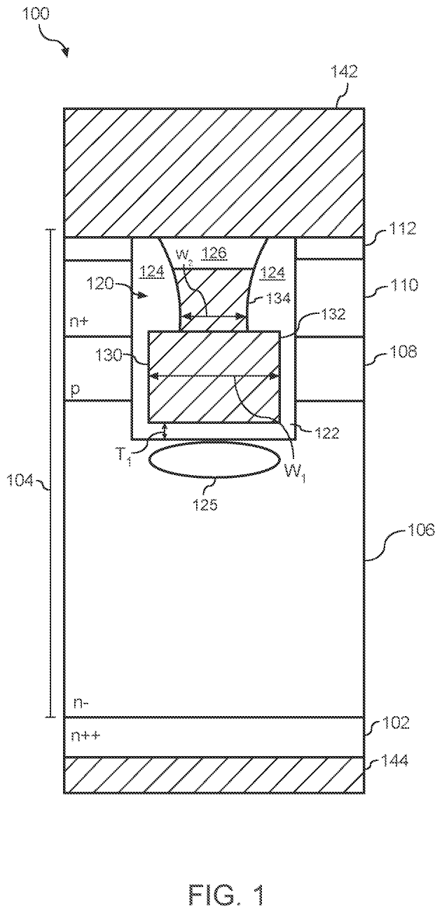

FIG. 1 depicts a cross-sectional view of an example unit cell of an example trench gate power semiconductor device 100 according to example embodiments of the present disclosure. The power semiconductor device 100 of FIG. 1 is a silicon carbide-based trench gate MOSFET. FIG. 1 is intended to represent structures for identification and description and is not intended to represent the structures to physical scale.

The power semiconductor device 100 includes a heavily-doped (n+) n-type silicon carbide substrate 102. The power semiconductor device 100 includes a wide bandgap semiconductor structure 104 (e.g., silicon carbide) on the silicon carbide substrate 102. The wide bandgap semiconductor structure 104 may be epitaxially formed on the substrate 102.

The wide bandgap semiconductor structure 104 may include a lightly-doped (n-) silicon carbide drift region 106 on the substrate 102. The lightly-doped silicon carbide drift region 106 may be formed on the substrate 102, for instance, by epitaxial growth.

A moderately-doped p-type silicon carbide well region 108 is on the drift region 106. The moderately-doped p-type well region 108 may provide p-wells for the power semiconductor device 100. The moderately-doped p-type well region 108 may be formed, for instance, by epitaxial growth.

A heavily-doped (n+) n-type silicon carbide layer 110 is on the well region 108. The heavily-doped n-type silicon carbide layer 110 may form a well tie-in region for the semiconductor device 100. The heavily-doped n-type silicon carbide layer 110 may be formed, for instance, at least in part, using ion implantation.

The semiconductor device includes a gate trench 120 in the wide bandgap semiconductor structure 104. The gate trench 120 extends through the heavily-doped n-type silicon carbide layer 110, the well region 108 and into the drift region 106. A gate dielectric layer 122 may be along a bottom surface and sidewalls of the gate trench 120. The gate dielectric layer 122 may be, for instance, an oxide layer. In some examples, the gate dielectric layer 122 includes one or more of, SiO₂, SiN, Al₂O₃, MgOₓ, MgNₓ, ZnO, SiNₓ, SiOₓ. In the example of FIG. 1, the gate dielectric layer 122 may have a thickness T1. The thickness T1 may be, for instance, in a range of about 150 Angstroms to about 550 Angstroms, such as about 250 Angstroms to about 550 Angstroms, such as about 300 Angstroms to about 400 Angstroms. Vertical channel regions are provided in the well region 108 adjacent to the gate dielectric layer 122.

The power semiconductor device 100 may include a field shield region 125 beneath the gate trench 120. The field shield region 125 may be a heavily-doped (p+) silicon carbide that is formed in the upper surface of the drift region 106, for instance, by ion implantation. The shield region 125 may be effective in protecting the corners of the gate dielectric layer 122 from high electric fields during reverse blocking operation. The shield region 125 may provide shielding for the gate dielectric layer 122 and may provide desired device performance resulting from utilization of two sidewall faces for current conduction.

According to example aspects of the present disclosure, a gate structure 130 may be buried within the gate trench 120. More particularly, the gate structure 130 may be completely within the gate trench 120 so that no portion of the gate structure 130 extends outside of the gate trench 120. In some examples, a top surface of the gate structure 130 may be at least about 1000 Angstroms to about 4000 Angstroms below a top of the gate trench 120, such as about 1500 Angstroms to about 3500 Angstroms below a top of the gate trench 120, such as about 2000 Angstroms to about 3000 Angstroms below a top of the gate trench 120.

The gate structure 130 may be a multilayer gate structure and may include a first gate layer 132 and a second gate layer 134. The first gate layer 132 may be, for instance, a polysilicon layer and may be referred to as a gate polysilicon layer. The second gate layer 134 may be, for instance, a silicide layer and may be referred to as a gate silicide layer.

In some examples, as shown in FIG. 1, the first gate layer 132 (e.g., the gate polysilicon layer) may have a width W1. The second gate layer 134 (e.g., the gate silicide layer) may have a width W2 at an interface between the first gate layer 132 and the second gate layer 134. The width W2 may be less than the width W1. In some examples, the second gate layer 134 (e.g., the gate silicide layer) may have a varying width. The second gate layer 134 (e.g., the gate silicide layer) may have curved or arcuate sidewalls. The second gate layer 134 may have other suitable shapes without deviating from the scope of the present disclosure.

In some examples, the second gate layer 134 (e.g., the gate silicide layer) includes tantalum silicide (Ta_{y}Siₓ) and/or tungsten silicide (W_{y}Siₓ). In some embodiments, x may be in a range of about 2.0 to about 3.0.

In some examples, the interface between the first gate layer 132 and the second gate layer 134 may be at a depth within the gate trench 120 that is proximate to a depth of the interface between the well region 108 and the highly-doped silicon carbide layer 110 (forming the well tie-in region). For instance, the interface between the first gate layer 132 and the second gate layer 134 may be above the interface between the well region 108 and the highly-doped silicon carbide layer 110 a distance in a range of about 0 nm to about 500 nm, such as about 0 nm to about 250 nm, such as about 50 nm to about 100 nm.

The semiconductor device 100 may include a spacer layer 124 in the gate trench 120. As will be discussed in detail below, the spacer layer 124 may facilitate formation of the second gate layer 134 (e.g., the gate silicide layer) of the gate structure 130 in the gate trench 120. The spacer layer 124 may be at least partially on the gate dielectric layer 122 and the first gate layer 132 (e.g., the gate polysilicon layer) of the gate structure 130. The spacer layer 124 may be between at least a portion of gate structure 130 and the sidewall of the gate trench 120. For instance, the spacer layer 124 may be between the second gate layer 134 (e.g., the gate silicide layer) and the sidewall of the gate trench 120. The spacer layer 124, in some examples, may be a dielectric material. In some examples, the spacer layer 124 is an oxide. In some examples, the spacer layer 124 is silicon dioxide or silicon nitride. Other suitable dielectric material(s) may be used as the spacer layer 124 without deviating from the scope of the present disclosure. For instance, in some examples, the spacer layer 124 may include one or more of, for instance, SiO₂, Si₃N₄, Al₂O₃, MgOₓ, MgNₓ, ZnO, SiNₓ, SiOₓ.

The semiconductor device 100 may further include a dielectric layer 126 in the gate trench 120. The dielectric layer 126 may be on the second gate layer 134 (e.g., the gate silicide layer) of the gate structure 130. The dielectric layer 126 may cover the gate structure 130 within the gate trench 120. The dielectric layer 126 may be in an opening defined in the spacer layer 124. The dielectric layer 126 may have a surface that is coplanar with a surface (e.g., a top surface) of the wide bandgap semiconductor structure 104. In some examples, the dielectric layer 126 is a silicate glass. For instance, the dielectric layer 126 may include a borosilicate glass and/or a borophosphosilicate glass (BPSG). Other suitable dielectric material(s) may be used as the dielectric layer 126 without deviating from the scope of the present disclosure. The dielectric layer 126 may electrically insulate a metallization layer 142 (e.g., source metallization layer) from the gate structure 130 buried in the gate trench 120.

More particularly, the semiconductor device 100 may be a vertical semiconductor device with a metallization layer 142 (e.g., source metallization layer) on an upper surface of the wide bandgap semiconductor structure 104. The semiconductor device 100 may include a metallization layer 144 (e.g., drain metallization layer) on the lower surface of the substrate 102. The metallization layer 142 and the metallization layer 144 may be a single material or may include multilayer structures with different materials. The metallization layer 142 and/or the metallization layer 144 may include metals suitable for forming an ohmic contact with the wide bandgap semiconductor structure 104. For instance, the metallization layer 142 and/or the metallization layer 144 may include one or more of titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), nickel silicide (NiSiₓ), titanium silicide (TiSiₓ), titanium nitride (TiN), tungsten silicon nitride (WSiN), platinum (Pt) and the like.

According to example aspects of the present disclosure, the metallization layer 142 may be a planar metallization layer 142. The metallization layer 142 may directly contact the dielectric layer 126. In some examples, the metallization layer 142 may directly contact the spacer layer 124.

The metallization layer 142 may contact the wide bandgap semiconductor structure 104. For instance, the metallization layer 142 may contact the wide bandgap semiconductor structure 104 through a well tie-in silicide layer 112 on an upper surface of the wide bandgap semiconductor structure 104. The well tie-in silicide layer 112 may facilitate forming an ohmic contact between the metallization layer 142 and the wide bandgap semiconductor structure 104.

In some examples, the well tie-in silicide layer 112 is the same material as the second gate layer 134 (e.g., the gate silicide layer) of the gate structure 130. In some examples, the well tie-in silicide layer 112 is a different material relative to the second gate layer 134 (e.g., the gate silicide layer) of the gate structure. In some examples, the well tie-in silicide layer 112 is one or more of nickel silicide, tungsten silicide, titanium silicide, aluminum silicide, molybdenum silicide, aluminum-titanium silicide, nickel-titanium-aluminum silicide or titanium-tungsten silicide.

The metallization layer 142 may contact the well-tie in regions of the wide bandgap semiconductor structure 104 without having to dive down or use a metallized plug in a contact hole. This may facilitate a reduction in pitch of the unit cells of the power semiconductor device 100, enhancing scalability.

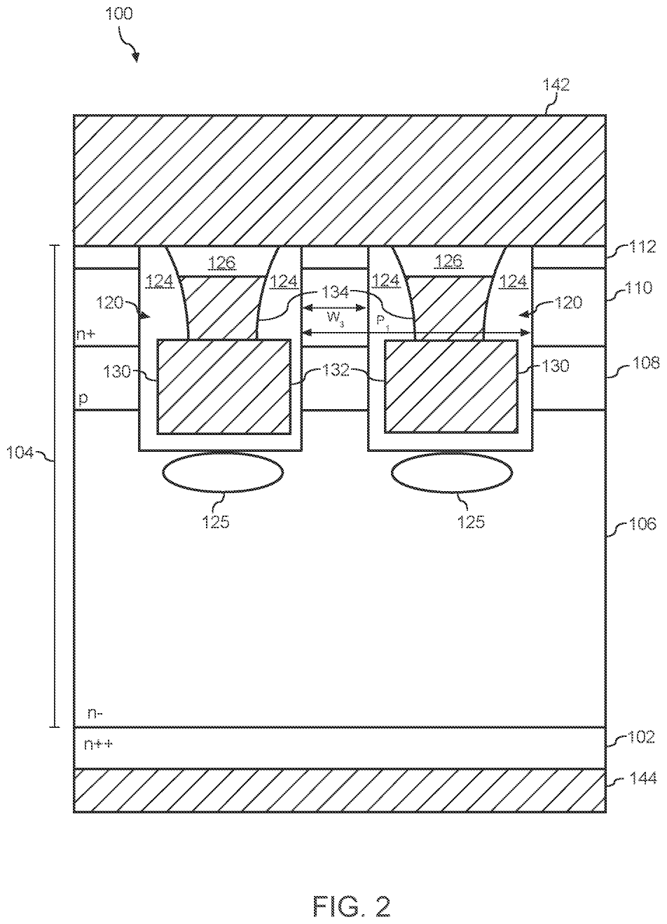

For instance, FIG. 2 depicts two example unit cells adjacent one another in a semiconductor device 100 according to example embodiments of the present disclosure. The power semiconductor device 100 of FIG. 2 is a silicon carbide-based trench gate MOSFET. FIG. 2 is intended to represent structures for identification and description and is not intended to represent the structures to physical scale. Because the gate structure 130 is buried within the gate trench 120 and because of the planar nature of the metallization layer 142 and the dielectric layer 126, the width W3 of the wide bandgap semiconductor structure 104 between gate trenches may be reduced. In some examples the width W3 may be in a range of about 25 nm to about 2000 nm, such as about 100 nm to about 1000 nm, such as about 200 nm to about 750 nm. This can result in a reduction in pitch P1 of unit cells in the semiconductor device 100. In some examples, the pitch P1 may be in a range of about 50 nm to about 4000 nm, such as about 200 nm to about 2000 nm, such as about 400 nm to about 1500 nm.

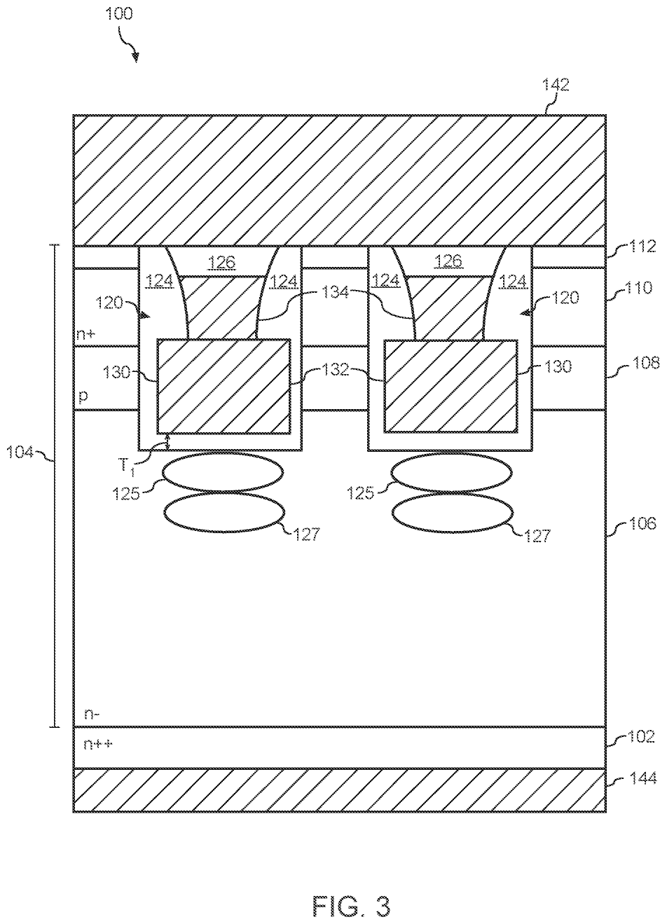

FIG. 3 depicts two example unit cells adjacent one another in a semiconductor device 100 according to example embodiments of the present disclosure. The power semiconductor device 100 of FIG. 3 is a silicon carbide-based trench gate MOSFET. FIG. 3 is intended to represent structures for identification and description and is not intended to represent the structures to physical scale. The semiconductor device 100 in FIG. 3 is similar to the semiconductor device in FIG. 1, except that the semiconductor device includes additional field shield regions 127 beneath the gate trench 120. In the example of FIG. 3, the semiconductor device 100 includes stacked field shield regions 125 and 127. More particularly, the first field shield region 125 is stacked with the second shield region 127 beneath the gate trench 120. In some examples, the additional shield regions may be stacked until electric field is reduced to a target level. In some examples, the shield regions 125 and/or 127 and/or the well regions 110 may be connected to the source metallization 142.

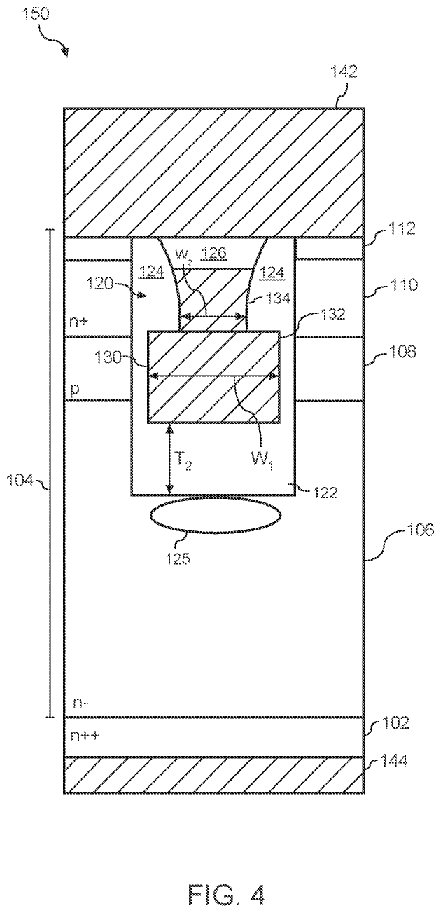

FIG. 4 depicts a cross-sectional view of an example unit cell of a semiconductor device 150 according to example embodiments of the present disclosure. The power semiconductor device 100 of FIG. 4 is a silicon carbide-based trench gate MOSFET. FIG. 4 is intended to represent structures for identification and description and is not intended to represent the structures to physical scale. The semiconductor device 150 of FIG. 4 is similar to the semiconductor device 100 of FIG. 1, except that the semiconductor device 150 has a thicker gate dielectric layer 122 in the gate trench 120 between the gate structure 130 and the drift region 106. In some examples, the gate dielectric layer 122 in the example of FIG. 4 can have a thickness T2. The thickness T2 may be in a range of about 500 Angstroms to about 2500 Angstroms, such as about 750 Angstroms to about 2000 Angstroms, such as about 1000 Angstroms to about 1750 Angstroms.

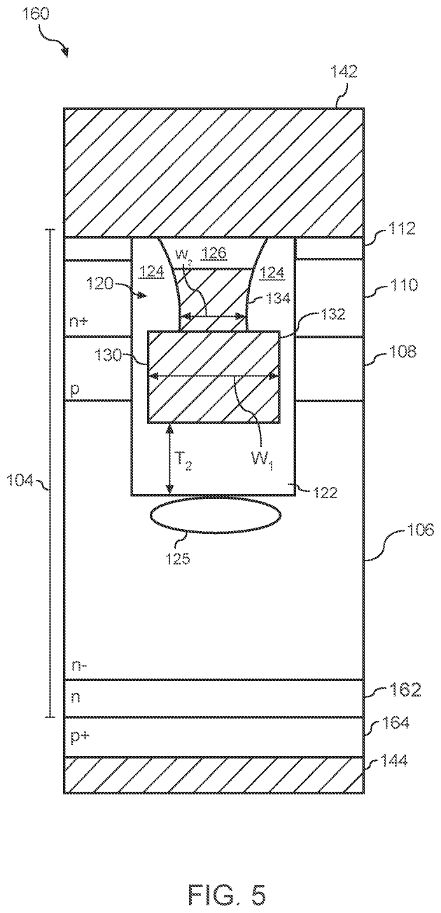

FIG. 5 depicts a cross-sectional view of an example unit cell of a semiconductor device 160 according to example embodiments of the present disclosure. The power semiconductor device 100 of FIG. 5 is a silicon carbide-based trench gate IGBT. FIG. 5 is intended to represent structures for identification and description and is not intended to represent the structures to physical scale. The semiconductor device 160 is similar to the semiconductor device 100 of FIG. 4, except that the semiconductor device 160 is an IGBT. The semiconductor device 160 includes a moderately-doped n-type silicon carbide field stop layer 162. Also the substrate may be a highly doped p-type silicon carbide emitter layer 164.

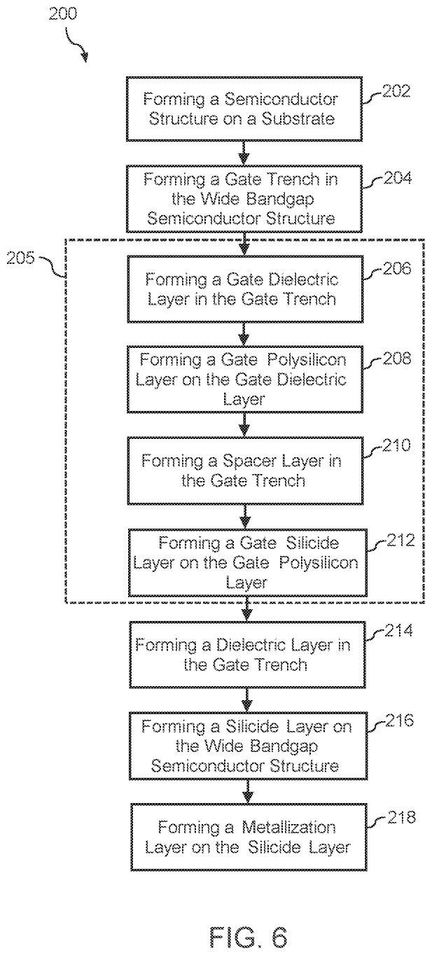

FIG. 6 depicts a flow chart diagram of an example method 200 for fabricating a semiconductor device according to example embodiments of the present disclosure. FIG. 6 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

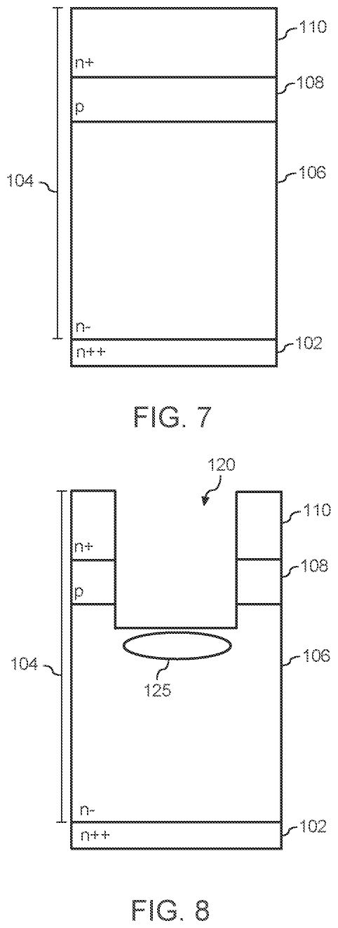

At 202, the method 200 may include forming a wide bandgap semiconductor structure (e.g., silicon carbide semiconductor structure) on a substrate (e.g., a silicon carbide substrate). For instance, as shown in FIG. 7, the method may include forming the wide bandgap semiconductor structure 104 on a substrate 102. The wide bandgap semiconductor structure 104 may be formed, for instance, using epitaxial growth. As illustrated, the silicon carbide semiconductor structure 104 may include a lightly-doped (n-) silicon carbide drift region 106 on the substrate 102. The lightly-doped silicon carbide drift region 106 may be formed on the substrate 102, for instance, by epitaxial growth. The wide bandgap semiconductor structure 104 may include a moderately-doped p-type silicon carbide well region 108 on the drift region 106. The moderately-doped p-type well region 108 may be formed, for instance, by epitaxial growth. The wide bandgap semiconductor structure 104 may include a heavily-doped n-type silicon carbide layer 110 is on the well region 108. The heavily-doped n-type silicon carbide layer 110 may be formed, for instance, at least in part, using ion implantation.

At 204, the method 200 may include forming a gate trench in the wide bandgap semiconductor structure. For instance, as shown in FIG. 8, the method may include forming a gate trench 120 in the wide bandgap semiconductor structure 104. The gate trench 120 may extend through the heavily-doped n-type silicon carbide layer 110, the well region 108, and into the drift region 106. In some examples, a field shield region 125 may be formed beneath the gate trench 120 using, for instance, ion implantation.

At 205, the method may include forming a buried gate structure in the gate trench. The buried gate structure may be a multilayer gate structure. For instance, the buried gate structure may include a gate polysilicon layer and a gate silicide layer on the gate polysilicon layer.

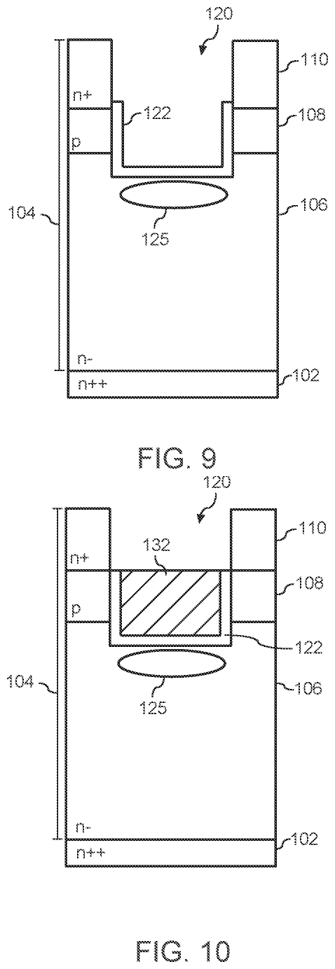

More particularly, in some examples, the method 200 may include at 206 forming a gate dielectric layer in the gate trench. For instance, as shown in FIG. 9, the method may include forming a gate dielectric layer 122 on the bottom and sidewalls of the gate trench 120. The gate dielectric layer 122 may be an oxide and may be formed using an oxidation process or a suitable deposition process. In some examples, the gate dielectric layer 122 may include one or more of, SiO₂, SiN, Al₂O₃, MgOₓ, MgNₓ, ZnO, SiNₓ, SiOₓ. Portions of the gate dielectric layer 122 may be etched away after deposition to form the structure of the gate dielectric layer 122 illustrated in FIG. 9.

At 208, the method 200 may include forming a gate polysilicon layer on the gate dielectric layer. For instance, as shown in FIG. 10, the method may include forming the first gate layer 132 (e.g., the gate polysilicon layer) of a gate structure on the gate dielectric layer 122. The gate polysilicon layer may be formed using a suitable deposition process. In some examples, the gate polysilicon layer may be formed using a chemical vapor deposition (CVD) process, a physical vapor deposition (PVD) process, a sputtering process, an atomic layer deposition (ALD) process, or other suitable deposition process. Portions of the gate polysilicon layer may be etched away after deposition to form the structure illustrated in FIG. 10.

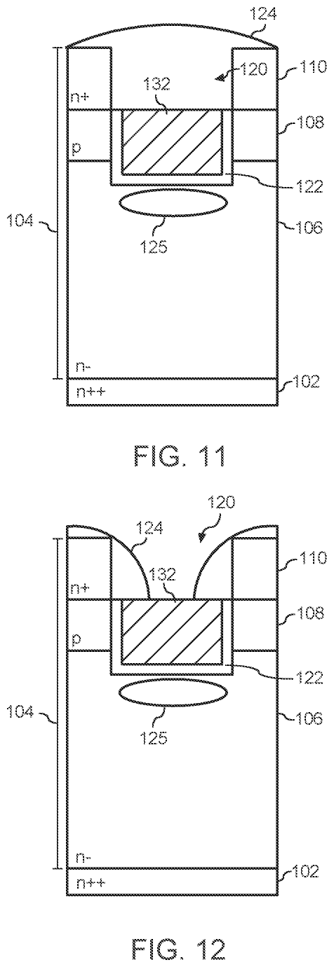

At 210, the method 200 may include forming a spacer layer in the gate trench. For instance, as shown in FIG. 11, the method may include depositing spacer material for the spacer layer 124 in the gate trench 120. The spacer material may extend out of the gate trench 120 and be at least partially on the upper surface of the wide bandgap semiconductor structure 104. The spacer material may be formed using a suitable deposition process, such as a chemical vapor deposition (CVD) process, a physical vapor deposition (PVD) process, a sputtering process, an atomic layer deposition (ALD) process, or other suitable deposition process. The spacer material may include a dielectric material, such as silicon dioxide, silicon nitride, or other suitable dielectric material. For instance, in some examples, the spacer material may be one or more of, for instance, SiO₂, Si₃N₄, Al₂O₃, MgOₓ, MgNₓ, ZnO, SiNₓ, SiOₓ.

As shown in FIG. 12, the method may include etching a hole in the spacer material to form the spacer layer 124 in the gate trench. At least a portion of the spacer material may remain on the upper surface of the wide bandgap semiconductor structure 104. This may serve to mask at least a portion of the wide bandgap semiconductor structure 104 during future gate formation steps (e.g., formation of the gate silicide layer) to reduce formation of, for instance, silicide on the wide bandgap semiconductor structure 104 during future process steps. Any suitable etch process may be used to etch the hole in the spacer material, such as a wet etch process or a plasma-based dry etch process.

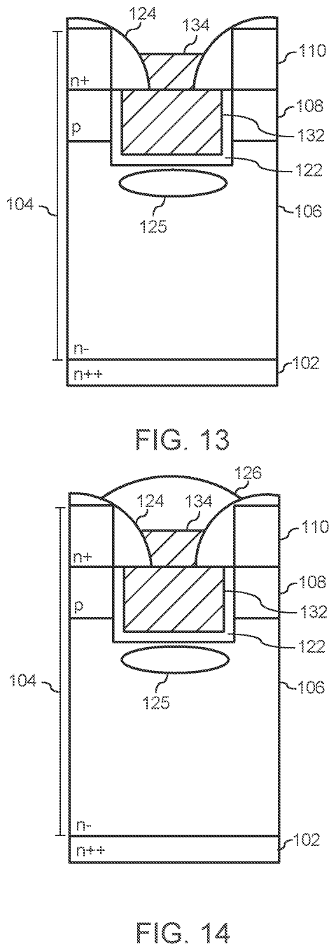

Referring to FIG. 6 at 212, the method 200 may include forming a gate silicide layer on the gate polysilicon layer. For instance, as shown in FIG. 13, the method may include forming the second gate layer 134 (e.g., the gate silicide layer) in the hole in the spacer layer 124. The second gate layer 134 (e.g., the gate silicide layer) may be completely within the gate trench 120. In some examples, the second gate layer 134 (e.g., the gate silicide layer) includes tantalum silicide Ta_{y}Siₓ or tungsten silicide W_{y}Siₓ, where x is in a range of about 2.0 to about 3.0. The second gate layer 134 (e.g., the gate silicide layer) may be formed using any suitable process for forming a silicide on the first gate layer 132 (e.g., the polysilicon layer). For instance, one or more metal deposition (e.g., tantalum deposition and/or tungsten deposition) steps and annealing steps may be implemented to form the second gate layer (e.g., the gate silicide layer).

At 214, the method 200 may include forming a dielectric layer in the gate trench. For instance, as shown in FIG. 14, the method may include forming dielectric material for the dielectric layer 126 in the gate trench 120. The dielectric material may extend out of the gate trench 120. The dielectric material may be formed using a suitable deposition process, such as a chemical vapor deposition (CVD) process, a physical vapor deposition (PVD) process, a sputtering process, an atomic layer deposition (ALD) process, or other suitable deposition process. In some examples, the dielectric layer may be a silicate glass, such as a borosilicate glass or a borophosphosilicate glass.

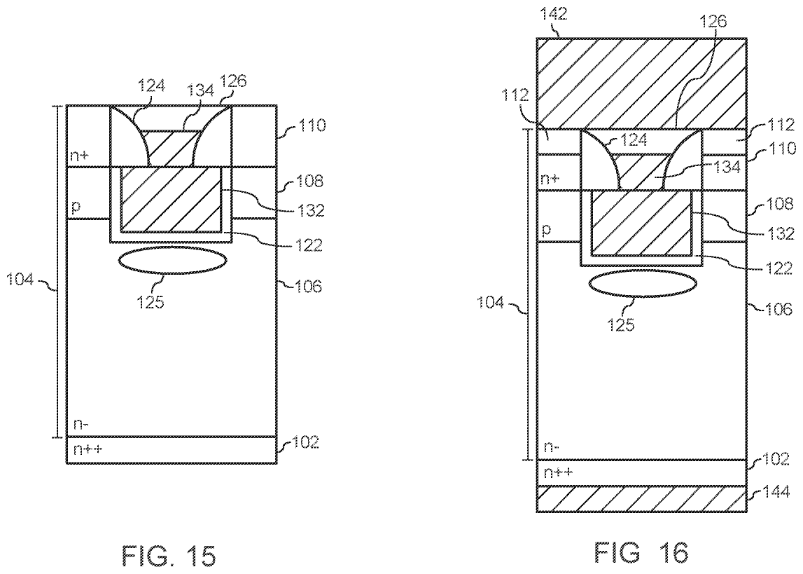

As shown in FIG. 15, forming the dielectric layer in the gate trench may include planarizing the dielectric layer 126 such that an upper surface of the dielectric layer 126 is coplanar with an upper surface of the wide bandgap semiconductor structure 104. For instance, the method may include etching the dielectric layer 126 and/or the spacer layer 124 so that an upper surface of the dielectric layer 126 and the spacer layer 124 is coplanar with the upper surface of the semiconductor structure 104. Planarizing the dielectric layer 126 and/or the spacer layer 124 may be performed using a wet etch process and/or a plasma-based dry etch process.

At 216 of FIG. 6, the method may include forming a silicide layer on the wide bandgap semiconductor structure. The silicide layer may facilitate ohmic contact of a metallization layer (e.g., source metallization layer) to the wide bandgap semiconductor structure 104. The silicide layer may be, for instance, nickel silicide, tungsten silicide, titanium silicide, aluminum silicide, molybdenum silicide, aluminum-titanium silicide, nickel-titanium-aluminum silicide or titanium-tungsten silicide. The silicide layer may be formed using any suitable process for forming a silicide on the wide bandgap semiconductor structure 104. For instance, one or more metal deposition steps and annealing steps may be implemented to form the silicide layer. FIG. 16 depicts the silicide layer 112 formed on the wide bandgap semiconductor structure 104.

At 218, the method may include forming a metallization layer on the silicide layer. The metallization layer may include a planar surface that directly contacts the dielectric layer in the gate trench and the wide bandgap semiconductor structure. For instance, as shown in FIG. 16, the method may include forming the metallization layer 142 (e.g., source metallization layer) such that a planar surface of the metallization layer 142 directly contacts the dielectric layer 126 and the wide bandgap semiconductor structure 104.

The metallization layer 142 may include metals suitable for forming an ohmic contact with the wide bandgap semiconductor structure 104. For instance, the metallization layer 142 may include one or more of titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), nickel silicide (NiSiₓ), titanium silicide (TiSiₓ), titanium nitride (TiN), tungsten silicon nitride (WSiN), platinum (Pt) and the like. The metallization layer 142 may be formed using a suitable deposition process, such as a chemical vapor deposition (CVD) process, a physical vapor deposition (PVD) process, a sputtering process, an atomic layer deposition (ALD) process, or other suitable deposition process.

Example aspects of the present disclosure are set forth below. Any of the below features or examples may be used in combination with any of the embodiments or features provided in the present disclosure.

One example embodiment of the present disclosure is directed to a semiconductor device. The semiconductor device includes a wide bandgap semiconductor structure. The wide bandgap semiconductor structure includes a drift region of a first conductivity type and a well region of a second conductivity type. The semiconductor device includes a gate trench in the wide bandgap semiconductor structure. The gate trench extends through the well region into the drift region. The semiconductor device includes a buried gate structure in the gate trench. The buried gate structure includes a gate polysilicon layer and a gate silicide layer.

In some examples, an upper surface of the gate silicide layer is below an upper surface of the wide bandgap semiconductor structure. In some examples, the buried gate structure is covered within the gate trench.

In some examples, the gate silicide layer comprises Ta_{y}Siₓ or W_{y}Siₓ. In some examples, x is in a range of about 2.0 to about 3.0.

In some examples, the gate polysilicon layer has a different width relative to a width of the gate silicide layer. In some examples, the gate polysilicon layer is between the gate silicide layer and a bottom surface of the gate trench. In some examples, the gate silicide layer is closer to an upper surface of the wide bandgap semiconductor structure relative to the gate polysilicon layer.

In some examples, the semiconductor device includes a dielectric layer in the gate trench on the buried gate structure. In some examples, the semiconductor device includes a metallization layer on the wide bandgap semiconductor structure. The metallization layer has a planar surface contacting the wide bandgap semiconductor structure and the dielectric layer. In some examples, the dielectric layer is arranged to electrically insulate the buried gate structure from the metallization layer. In some examples, the dielectric layer has an upper surface that is coplanar with an upper surface of the semiconductor structure. In some examples, the dielectric layer is a silicate glass.

In some examples, the semiconductor device includes a spacer layer in the gate trench, the spacer layer between at least a portion of the buried gate structure and a sidewall of the gate trench. In some examples, the spacer layer includes silicon dioxide or silicon nitride. In some examples, the spacer layer is between at least a portion of a dielectric layer on the buried gate structure and a sidewall of the gate trench.

In some examples, the semiconductor device includes a gate dielectric layer between the buried gate structure and the drift region. In some examples, the gate dielectric layer has a thickness between the buried gate structure and a bottom surface of the buried gate structure, the thickness being in a range of about 250 Angstroms to about 2500 Angstroms.

In some examples, the semiconductor structure comprises a second silicide layer on an upper surface of the wide bandgap semiconductor structure. In some examples, the second silicide layer is a different material relative to the gate silicide layer. In some examples, the second silicide layer includes nickel silicide, tungsten silicide, titanium silicide, aluminum silicide, molybdenum silicide, aluminum-titanium silicide, nickel-titanium-aluminum silicide or titanium-tungsten silicide.

In some examples, the wide bandgap semiconductor structure further includes a shield region beneath the gate trench, the shield region having the second conductivity type.

In some examples, the wide bandgap semiconductor structure includes silicon carbide.

In some examples, the semiconductor device is a MOSFET.

In some examples, the semiconductor device is an insulated gate bipolar transistor (IGBT).

Another example embodiment of the present disclosure is directed to a semiconductor device. The semiconductor device includes a wide bandgap semiconductor structure. The wide bandgap semiconductor structure includes a drift region of a first conductivity type and a well region of a second conductivity type. The semiconductor device includes a gate trench in the wide bandgap semiconductor structure. The gate trench extends through the well region into the drift region. The semiconductor device includes a gate structure in the gate trench. The semiconductor device includes a dielectric layer in the gate trench on the gate structure. The semiconductor device includes a spacer layer in the gate trench and between the dielectric layer and a sidewall of the gate trench. The semiconductor device includes a gate dielectric layer in the gate trench between the gate structure and the drift region.

In some examples, an upper surface of the gate structure is below an upper surface of the wide bandgap semiconductor structure. In some examples, the gate structure is covered within the gate trench.

In some examples, the semiconductor device includes a metallization layer. The metallization layer has a planar surface directly contacting an upper surface of the wide bandgap semiconductor structure and the dielectric layer. In some examples, the dielectric layer is arranged to electrically insulate the gate structure from the metallization layer.

In some examples, the wide bandgap semiconductor structure includes a silicide layer contacting the metallization layer. In some examples, the silicide layer includes nickel silicide, tungsten silicide, titanium silicide, aluminum silicide, molybdenum silicide, aluminum-titanium silicide, nickel-titanium-aluminum silicide or titanium-tungsten silicide.

In some examples, the gate structure has a first gate layer and a second gate layer on the first gate layer. The first gate layer is a different material relative to the second gate layer. In some examples, the first gate layer includes polysilicon and the second gate layer includes silicide. In some examples, the silicide is Ta_{y}Siₓ or W_{y}Siₓ. In some examples, x is in a range of about 2.0 to about 3.0

In some examples, the first gate layer has a different width relative to a width of the second gate layer. In some examples, the first gate layer is between the second gate layer and a bottom surface of the gate trench. In some examples, the second gate layer is closer to an upper surface of the wide bandgap semiconductor structure relative to the first gate layer.

In some examples, the dielectric layer has an upper surface that is coplanar with an upper surface of the wide bandgap semiconductor structure. In some examples, the dielectric layer is a different material relative to the spacer layer. In some examples, the dielectric layer is a silicate glass.

In some examples, the spacer layer includes silicon dioxide or silicon nitride.

In some examples, the gate dielectric layer has a thickness between the gate structure and a bottom surface of the gate structure. The thickness is in a range of about 250 Angstroms to about 2500 Angstroms.

In some examples, the wide bandgap semiconductor structure further includes a shield region beneath the gate trench, the shield region having the second conductivity type.

In some examples, the wide bandgap semiconductor structure comprises silicon carbide.

In some examples, the semiconductor device is a MOSFET.

In some examples, the semiconductor device is an insulated gate bipolar transistor (IGBT).

Another example embodiment of the present disclosure is directed to a method of fabricating a semiconductor device. The method includes forming a gate trench in a wide bandgap semiconductor structure. The method includes forming a buried gate structure in the gate trench. The buried gate structure includes a gate polysilicon layer and a gate silicide layer. The method includes forming a dielectric layer in the gate trench on the buried gate structure.

In some examples, the wide bandgap semiconductor structure includes a drift region of a first conductivity type and a well region of a second conductivity type. Forming the gate trench includes forming the gate trench extending through the well region and into the drift region.

In some examples, forming the buried gate structure includes: forming a gate dielectric layer in the gate trench; forming the gate polysilicon layer on the gate dielectric layer; forming a spacer layer in the gate trench; and forming the gate silicide layer on the gate polysilicon layer.

In some examples, the gate silicide layer comprises Ta_{y}Siₓ or W_{y}Siₓ. In some examples, x is in a range of about 2.0 to about 3.0. In some examples, the gate dielectric layer has a thickness in a range of about 250 Angstroms to about 2500 Angstroms.

In some examples, the method includes forming a second silicide layer on the wide bandgap semiconductor structure; and forming a metallization layer on the second silicide layer.

In some examples, forming the metallization layer includes forming the metallization layer such that the metallization layer directly contacts the dielectric layer. In some examples, forming the dielectric layer includes planarizing the dielectric layer with an upper surface of the wide bandgap semiconductor structure.

In some examples, the dielectric layer covers the buried gate structure in the gate trench.

In some examples, the semiconductor device is a MOSFET.

In some examples, the semiconductor device is an insulated gate bipolar transistor (IGBT).

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a wide bandgap semiconductor structure, the wide bandgap semiconductor structure comprising a drift region of a first conductivity type and a well region of a second conductivity type;
a gate trench in the wide bandgap semiconductor structure, the gate trench extending through the well region into the drift region; and
a buried gate structure in the gate trench, the buried gate structure comprising a gate polysilicon layer and a gate silicide layer.

2. The semiconductor device of claim 1, wherein an upper surface of the gate silicide layer is below an upper surface of the wide bandgap semiconductor structure.

3. The semiconductor device of claim 1, wherein the buried gate structure is covered within the gate trench.

4. The semiconductor device of claim 1, wherein the gate silicide layer comprises Ta_{y}Siₓ or W_{y}Siₓ, wherein x is in a range of about 2.0 to about 3.0.

5. (canceled)

6. The semiconductor device of claim 1, wherein the gate polysilicon layer has a different width relative to a width of the gate silicide layer.

7. The semiconductor device of claim 1, wherein the gate polysilicon layer is between the gate silicide layer and a bottom surface of the gate trench.

8. The semiconductor device of claim 1, wherein the gate silicide layer is closer to an upper surface of the wide bandgap semiconductor structure relative to the gate polysilicon layer.

9. The semiconductor device of claim 1, further comprising a dielectric layer in the gate trench on the buried gate structure.

10. The semiconductor device of claim 9, further comprising a metallization layer on the wide bandgap semiconductor structure, the metallization layer having a planar surface contacting the wide bandgap semiconductor structure and the dielectric layer, wherein the dielectric layer is arranged to electrically insulate the buried gate structure from the metallization layer.

11. (canceled)

12. The semiconductor device of claim 9, wherein the dielectric layer has an upper surface that is coplanar with an upper surface of the semiconductor structure.

13. The semiconductor device of claim 9, wherein the dielectric layer is a silicate glass.

14. The semiconductor device of claim 1, further comprising a spacer layer in the gate trench, the spacer layer between at least a portion of the buried gate structure and a sidewall of the gate trench.

15. The semiconductor device of claim 14, wherein the spacer layer comprises silicon dioxide or silicon nitride.

16. (canceled)

17. The semiconductor device of claim 1, further comprising a gate dielectric layer between the buried gate structure and the drift region, wherein the gate dielectric layer has a thickness between the buried gate structure and a bottom surface of the buried gate structure, the thickness being in a range of about 250 Angstroms to about 2500 Angstroms.

18. (canceled)

19. The semiconductor device of claim 1, wherein the semiconductor structure comprises a second silicide layer on an upper surface of the wide bandgap semiconductor structure, wherein the second silicide layer is a different material relative to the gate silicide layer, wherein the second silicide layer comprises nickel silicide, tungsten silicide, titanium silicide, aluminum silicide, molybdenum silicide, aluminum-titanium silicide, nickel-titanium-aluminum silicide or titanium-tungsten silicide.

20. (canceled)

21. (canceled)

22. The semiconductor device of claim 1, wherein the wide bandgap semiconductor structure further comprises a shield region beneath the gate trench, the shield region having the second conductivity type.

23. The semiconductor device of claim 1, wherein the wide bandgap semiconductor structure comprises silicon carbide.

24. The semiconductor device of claim 1, wherein the semiconductor device is a MOSFET or an insulated gate bipolar transistor (IGBT).

25. (canceled)

26. A semiconductor device, comprising:
a wide bandgap semiconductor structure, the wide bandgap semiconductor structure comprising a drift region of a first conductivity type and a well region of a second conductivity type;
a gate trench in the wide bandgap semiconductor structure, the gate trench extending through the well region into the drift region;
a gate structure in the gate trench;
a dielectric layer in the gate trench and on the gate structure;
a spacer layer in the gate trench and between the dielectric layer and a sidewall of the gate trench; and
a gate dielectric layer in the gate trench between the gate structure and the drift region.

27.-48. (canceled)

49. A method of fabricating a semiconductor device, the method comprising:
forming a gate trench in a wide bandgap semiconductor structure;
forming a buried gate structure in the gate trench, the buried gate structure comprising a gate polysilicon layer and a gate silicide layer; and
forming a dielectric layer in the gate trench and on the buried gate structure.

50.-60. (canceled)
